(19) United States
(12) Patent Application Publication
(10) Pub. No.: US 2009/0127441 A1
(43) Pub. Date: May 21, 2009

(54) Image Sensor and Method for Manufacturing Thereof

(76) Inventor: Sang Il Hwang, Wonju-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/256,533

(22) Filed: Oct. 23, 2008

(30) Foreign Application Priority Data
Nov. 16, 2007 (KR) 10-2007-0117023

(51) Int. Cl. H01L 31/0232

(52) U.S. Cl. 250/227.2; 438/29; 257/E31.127

(57) ABSTRACT

An image sensor according to an embodiment can comprise a metal line layer formed on a semiconductor substrate including a light receiving device; a first microlens formed on the metal line layer; a color filter array formed on the first microlens; and a second microlens formed on the color filter array. An oxide layer pattern can be disposed between the metal line layer and the first microlens. A blocking layer can be arranged in the oxide layer pattern in regions between adjacent first microlenses.

### CROSS-REFERENCE TO RELATED APPLICATION

The present application claims the benefit under 35 U.S.C. §119 of Korean Patent Application No. 10-2007-0117023, filed Nov. 16, 2007, which is hereby incorporated by reference in its entirety.

### BACKGROUND

An image sensor is a semiconductor device for converting an optical image into an electrical signal. Image sensors are generally classified as a charge coupled device (CCD) image sensor or a complementary metal oxide semiconductor (CMOS) image sensor.

The CMOS image sensor includes a photodiode and a MOS transistor within a unit pixel to sequentially detect electrical signals of each unit pixel using a switching scheme, thereby implementing an image.

### BRIEF SUMMARY

Embodiments of the present invention relate to an image sensor and method for manufacturing thereof. An image sensor according to an embodiment can comprise a metal line layer formed on a semiconductor substrate including a light receiving device; a first micro lens formed on the metal line layer; a color filter array formed on the first micro lens; and a second micro lens formed on the color filter array.

A method for manufacturing an image sensor according to an embodiment can comprise of: forming a metal line layer on a semiconductor substrate including a light receiving device; forming a first micro lens on the metal line layer; forming a first planarization layer on the first micro lens; forming a color filter array on the first planarization layer; and forming a second micro lens on the color filter array.

### BRIEF DESCRIPTION OF THE DRAWINGS

FIGS. 1 to 9 are cross-sectional views for describing a method for manufacturing an image sensor according to an embodiment of the present invention.

### DETAILED DESCRIPTION

Hereinafter, an image sensor and a method for manufacturing thereof according to an embodiment will be described with reference to the accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present. In the drawings, thickness or size of elements may be exaggerated or omitted or are schematically shown for convenience and clarity of explanation. Also, the size of each component is not necessarily shown to the scale.

Although the present embodiment is described with respect to a structure of a CMOS image sensor, embodiments of the present invention are not limited to the CMOS image sensor. For example, certain embodiments are applicable as a CCD image senor.

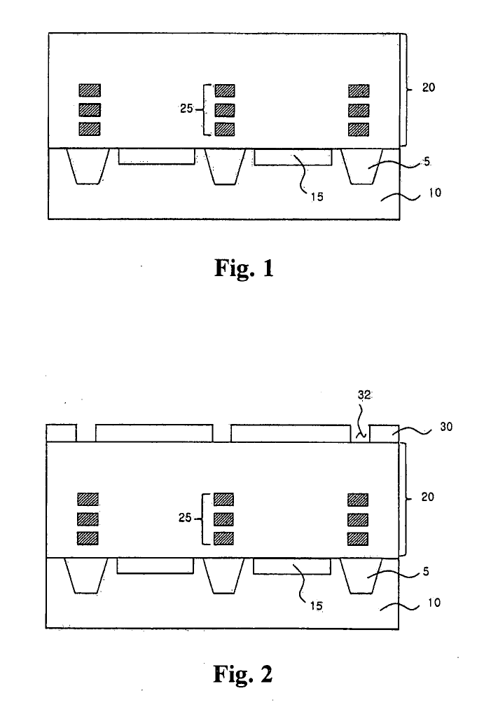

FIGS. 1 to 9 are cross-sectional views showing a formation of an image sensor according to an embodiment.

Referring to FIG. 1, a metal line layer 20 can be formed on a semiconductor substrate 10 on which a device isolating layer 5 and a light receiving device 15 are formed.

The semiconductor substrate 10 can include a low-concentration p-type epi layer on a high-concentration p++ type silicon substrate.

The inclusion of the p-type epi layer can increase the ability of a photodiode to collect photo charges by making a depletion region of the photodiode large and deep due. Also, if the high-concentration p++ type substrate is formed below a p-type epi layer, charges can be recombined before charges are diffused into a unit pixel, making it possible to reduce a random diffusion of the photo charges and a change in the photo charge transfer function.

The device isolating layer 5 can be formed, for example, by forming a trench in the semiconductor substrate 10 and filling the trench with an insulating material. The device isolating layer 5 can be used to define boundaries of unit pixel.

The light receiving device 15 can be, but is not limited to, a photodiode.

The metal line layer 20 can be formed on the substrate 10 and can be formed including a metal line 25. The metal line layer 20 can include a plurality of layers. The metal line 25 can be arranged so as to not cover the light receiving device 15.

Referring to FIG. 2, an oxide film pattern 30 can be formed on the metal line layer 20.

The oxide film 30 can be formed by forming a first oxide film on the metal line layer 20 and then performing a first etch processing to form a trench 32 in the first oxide film.

The trench 32 is disposed between the oxide film patterns 30 can be formed at a position corresponding to the metal line 25.

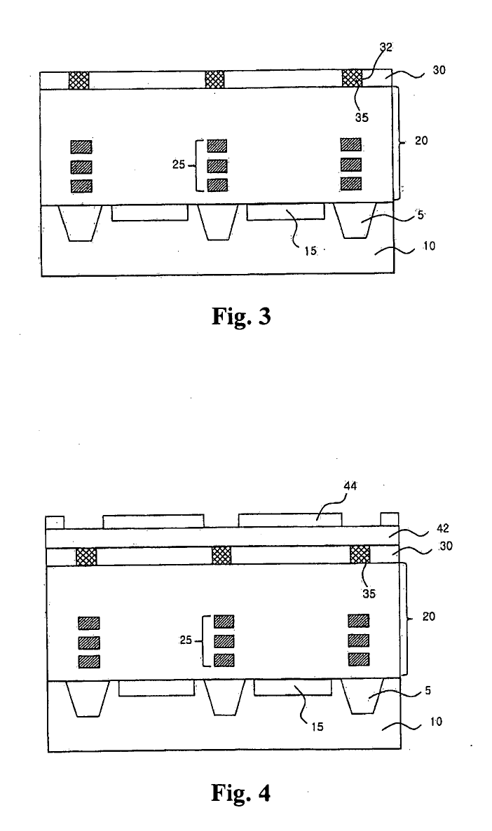

Referring to FIG. 3, a blocking layer 35 can be formed in the trench 32.

The blocking layer 35 can be formed by forming a metal layer on the oxide film pattern 30 including the trench 32 and then performing a planarization process.

The blocking layer 35 can include TiN. The blocking layer 35 can block light incident to the metal line 25 to inhibit cross talk, making it possible to reduce an occurrence of noise in the image sensor.

Then, referring to FIG. 4, a second oxide layer 42 and a first photoresist pattern 44 can be formed on the oxide film pattern 30 including the blocking layer 35.

The first photoresist pattern 44 can be formed to have a smaller width than that of the oxide pattern 30.

The first photoresist pattern 44 can be formed by coating the substrate 10 with a first photoresist layer and performing exposure and development processes thereon.

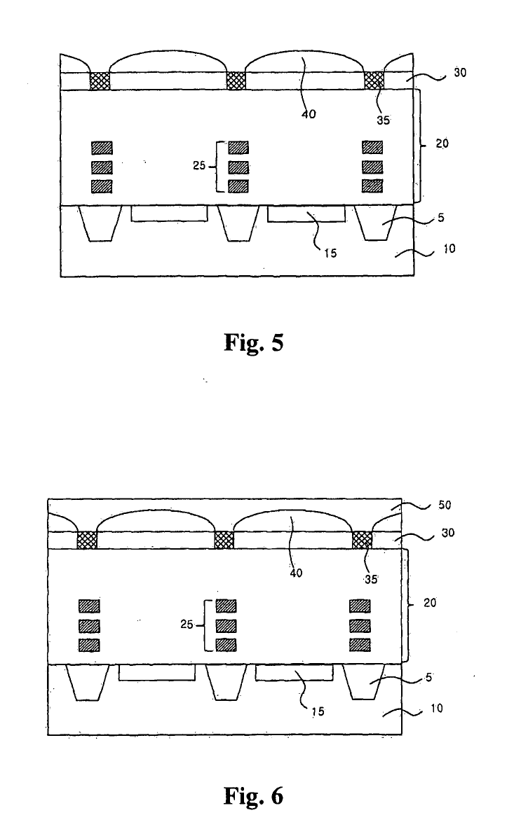

Then, referring to FIG. 5, a second etch process can be performed with respect to the second oxide film 42 using the first photoresist pattern 44 to form the first microlens 40.

In one embodiment, the second etch process can be performed by a chemical dry etch.

Upon performing the second etch process, the second oxide film 42 exposed between edges of the first photoresist pattern 44 is rapidly etched.

In other words, the etch is performed on an upper surface and a side surface of the edge region of the first photoresist pattern 44 so that it is more rapidly performed than a middle region of the first photoresist pattern 44.

Therefore, the etch is less performed as it goes to the middle region of the first photoresist pattern 44, making it possible to form first microlens 40, having a dome-like shape.

At this time, the thickness of the first photoresist pattern 44 can be thinly formed so that the entire first photoresist pattern 44 can be etched by the second etch process.

In a specific embodiment, the second etch process can be performed using O₂ gas with a flow rate of 10 to 500 sccm, N₂ gas with a flow rate of 10 to 200 sccm, and a CF₄ gas atmosphere with a flow rate of 10 to 500 sccm with a power of 10 to 2000 W at a pressure of pascal.

After the first microlens 40 is formed, a cleaning process removing the remaining photoresist and impurity can be performed.

Then, as shown in FIG. 6, a first planarization layer 50 can be formed on the first microlens 40.

The first planarization layer 50 can be formed by using a second photoresist layer.

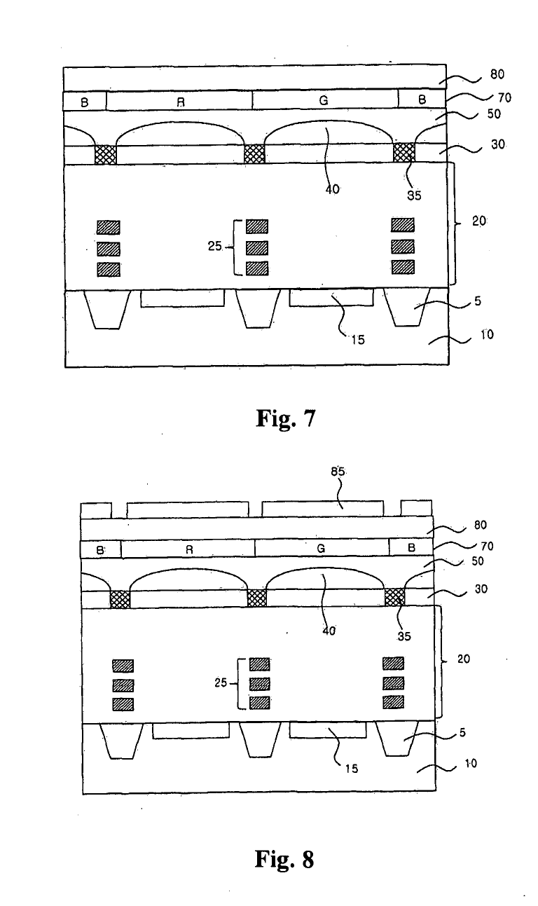

Referring to FIG. 7, a color filter array 70 and a second planarization layer 80 can be formed on the first planarization layer 50.

The second planarization layer 80 can be formed by using a third photoresist layer.

Then, as shown in FIG. 8, a second photoresist pattern 85 can be formed on the second planarization layer 80.

The second photoresist pattern 85 can be formed by forming a fourth photoresist layer on the second planarization layer 80 and then performing exposure and development processes thereon.

Also, the second photoresist pattern 85 can be formed by using a photoresist for forming the microlens.

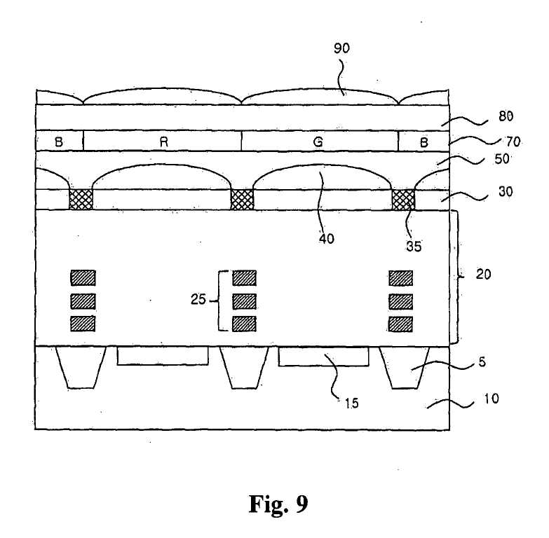

Accordingly, a reflow process can be performed with respect to the second photoresist pattern 85 to form a second microlens 90, as shown in FIG. 9.

In one embodiment, the reflow process can be performed at an exposure energy of 200 to 300 mJ/cm² and a temperature of 180 to 220° C.

The second microlens 90 can be formed to be smaller than the first microlens 40 by the reflow process.

FIG. 9 is a cross-sectional view of an image sensor according to an embodiment.

The image sensor according to an embodiment can include a metal line layer 20, an oxide layer pattern 30 including a blocking layer 35, a first microlens 40, a first planarization layer 50, a color filter array 70, a second planarization layer 80, and a second microlens 90 on a semiconductor substrate 10 including a light receiving device 15.

The light receiving device 15 can be a photo diode. The metal line layer 20 formed on the semiconductor substrate 10 can include a metal line 25.

The blocking layer 35 can be formed on the metal line layer 20 and can be disposed between the first microlenses 40.

The first microlens 40 can be formed on the oxide pattern 30 on which the blocking layer 35 is formed, and is formed in a region corresponding to the light receiving device 15.

Also, the first microlens 40 can be formed of an oxide layer.

The first planarization layer 50 can be formed on the first microlens 40 and the color filter array 70 and the second planarization layer 80 can be formed on the first microlens 40.

The second microlens 90 can be formed on the second planarization layer 80 and the curvature of the second microlens 90 can be formed to be smaller than that of the first microlens 40.

In other words, the curvature of the first microlens 40 can be formed to be larger than that of the second microlens 90.

As described above, a method for manufacturing an image sensor according to embodiments forms two microlenses to more effectively concentrate incident light on the light receiving device, making it possible to improve the sensitivity of the image sensor.

Also, a blocking layer can be formed between the microlenses to block light incident to the metal line to inhibit cross talk, making it possible to reduce the occurrence of noise in the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a metal line layer on a semiconductor substrate including a light receiving device;
a first microlens on the metal line layer;
a color filter array on the first microlens; and
a second microlens on the color filter array.

2. The image sensor according to claim 1, wherein the first microlens has a larger curvature than the second microlens.

3. The image sensor according to claim 1, wherein the first microlens comprises an oxide film.

4. The image sensor according to claim 1, further comprising a first planarization layer between the first microlens and the color filter array.

5. The image sensor according to claim 1, further comprising a second planarization layer between the color filter array and the second microlens.

6. The image sensor according to claim 1, further comprising an insulating layer between the metal line layer and the first microlens, wherein a blocking layer is disposed in the insulating layer at regions between the first microlenses and an adjacent first microlens.

7. A method for manufacturing an image sensor, comprising:
forming a metal line layer on a semiconductor substrate including a light receiving device;
forming a first microlens on the metal line layer;
forming a first planarization layer on the first microlens;
forming a color filter array on the first planarization layer; and
forming a second microlens on the color filter array.

8. The method according to claim 7, before forming the second microlens, further comprising forming a second planarization layer on the color filter array.

9. The method according to claim 7, wherein the first microlens has a larger curvature than the second microlens.

10. The method according to claim 7, further comprising before forming the first microlens,
forming a first oxide film on the metal line layer;
forming a trench in the first oxide film wherein the trench is disposed in regions between the first microlens and an adjacent first microlens; and
filling the trench with a metal material.

11. The method according to claim 7, wherein forming the first microlens on the metal line layer comprises:
forming a second oxide film on the metal line layer;
forming a photoresist pattern on the second oxide film; and
forming the first microlens on the metal line layer by performing a chemical dry etch with respect to the second oxide film using the photoresist pattern as an etch mask.

12. The method according to claim 11, wherein forming the second microlens comprises:
forming a second photoresist pattern on the color filter array; and
performing a reflow process with respect to the second photoresist pattern.
